(19) United States
(12) Patent Application Publication
(10) Pub. No.: US 2025/0309146 A1
(43) Pub. Date: Oct. 2, 2025

(54) EMBEDDED COMPONENT IN GLASS CORE

(71) Applicant: Intel Corporation, Santa Clara, CA (US)

(72) Inventors: Brandon C. MARIN, Gilbert, AZ (US); Teng SUN, Chandler, AZ (US); Srinivas Venkata Ramanuja PIETAMBARAM, Chandler, AZ (US); Cary KULIASHA, Mesa, AZ (US)

(21) Appl. No.: 18/620,727

(22) Filed: Mar. 28, 2024

(51) Int. Cl. H01L 23/58; H01L 21/48; H01L 23/00; H01L 23/31; H01L 23/498; H01L 25/16

(52) U.S. Cl. CPC H01L 23/58; H01L 21/486; H01L 23/3121; H01L 23/49838; H01L 24/19; H01L 24/20; H01L 25/16; H01L 23/49827; H01L 2224/19; H01L 2224/211; H01L 2224/221

(57) ABSTRACT

Embodiments disclosed herein comprise an apparatus with a substrate, where the substrate comprises a glass layer. In an embodiment, a hole is provided through a thickness of the substrate, and a component is in the hole, where the component comprises a first pad. In an embodiment, a via is through a thickness of the substrate, where a second pad is over an end of the via. In an embodiment, a first surface of the first pad is substantially coplanar with a second surface of the second pad, and a layer is over the substrate. In an embodiment, the layer fills at least a portion of the hole.

### BACKGROUND

Inductor components are integrated into the package substrate for power delivery applications. In existing applications, power delivery efficiency is increased by using magnetic materials to encase plated through holes (PTHs) to create coaxial metal inductor loops. Such coaxial metal inductor loops are integrated into glass cloth reinforced epoxy cores.

Demands for increased mechanical stability, such as warpage reduction, increased planarity, increased thickness uniformity, and/or the like, have driven a transition to glass cores. In a glass core, the reinforced epoxy layer is replaced with a solid glass layer. Currently, there is no avenue to replicate the formation of coaxial metal inductor loops in glass cores.

### BRIEF DESCRIPTION OF THE DRAWINGS

FIG. 1A is a cross-sectional illustration of a portion of a package substrate with a glass core and a component embedded in a hole through the glass core, in accordance with an embodiment.

FIG. 1B is a cross-sectional illustration of a portion of a package substrate with a glass core and a component embedded in a hole through the glass core with vias coupled to a top and bottom surface of the component, in accordance with an embodiment.

FIG. 1C is a cross-sectional illustration of a portion of a package substrate with a glass core and a plurality of components embedded in a hole through the glass core, in accordance with an embodiment.

FIGS. 2A-2M are cross-sectional illustrations depicting a process for forming a package substrate with a glass core and an embedded component within the glass core, in accordance with an embodiment.

FIGS. 3A and 3B are cross-sectional illustrations depicting a portion of a process for forming a package substrate with a glass core and an embedded component that is contacted on both sides by vias, in accordance with an embodiment.

FIG. 4 is a process flow diagram of a process for forming a package substrate with a glass core and a component embedded in a hole through a thickness of the glass core, in accordance with an embodiment.

FIG. 5 is a cross-sectional illustration of a package substrate with a glass core with a component embedded in a hole through a thickness of the glass core, in accordance with an embodiment.

FIG. 6 is a cross-sectional illustration of an electronic system that comprises a package substrate with a glass core and an embedded component, in accordance with an embodiment.

FIG. 7 is a schematic of a computing device built in accordance with an embodiment.

### DETAILED DESCRIPTION

Described herein are electronic systems, and more particularly, package substrates with a glass cores with embedded components, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, the existing coaxial metal inductor loops are not compatible with newly developed glass core package substrates. Further, existing coaxial metal inductor loop structures are not compatible with high voltage applications. For example, voltage requirements for high voltage devices (e.g., gallium nitrogen (GaN) voltage regulation devices) may be approximately 3V or higher. Accordingly, a new architecture suitable for integration with glass cores and capable of supporting higher voltages is desired to continue providing sufficient power delivery control for advanced applications.

One solution for accommodating higher voltages is through the use of metal inductor arrays (MIAs). MIAs comprise electrical traces that are embedded within a magnetic microparticle material, such as one based on an iron-alloy system. The magnetic microparticle material enhances the inductance of the embedded trace. For example, the high permeability of the magnetic microparticle material lowers the reluctance of the main flux path within the MIA in order to increase the inductance of the trace. Generally, the MIA is manufactured as a three dimensional block with pads on a surface of the block. The pads are electrically coupled to the traces within the block used to form the inductor. Such a solution allows for high inductances suitable for voltages above 3V.

The MIA may be integrated into the core of the package substrate. This provides several benefits, such as one or more of preservation of valuable real estate, a reduction in a distance between the MIA and the die, and/or a reduction in a thickness of the package substrate. Accordingly, embodiments disclosed herein provide architectures with MIA components embedded within a glass core and process flows designed to enable such architectures.

While power delivery improvements are one goal of embodiments disclosed herein, it is to be appreciated that processes disclosed herein may be leveraged in order to embed any type of component within a glass core of a package substrate. For example, other passive electrical devices (e.g., capacitors (e.g., deep trench capacitors (DTCs)), resistors, and/or the like) may be embedded in a glass core. Active devices or dies may also be embedded in the glass core in accordance with embodiments disclosed herein. For example, processors (e.g., a central processing unit (CPU), an XPU, a communications die, or any other die with transistors for providing some computational function), memories (e.g., high bandwidth memory (HBM)), and/or the like may be embedded within a glass core in accordance with embodiments disclosed herein. More generally, references herein to a “component” may refer to any of the components described herein, or any other conceivable component that is to be embedded within a core of a package substrate.

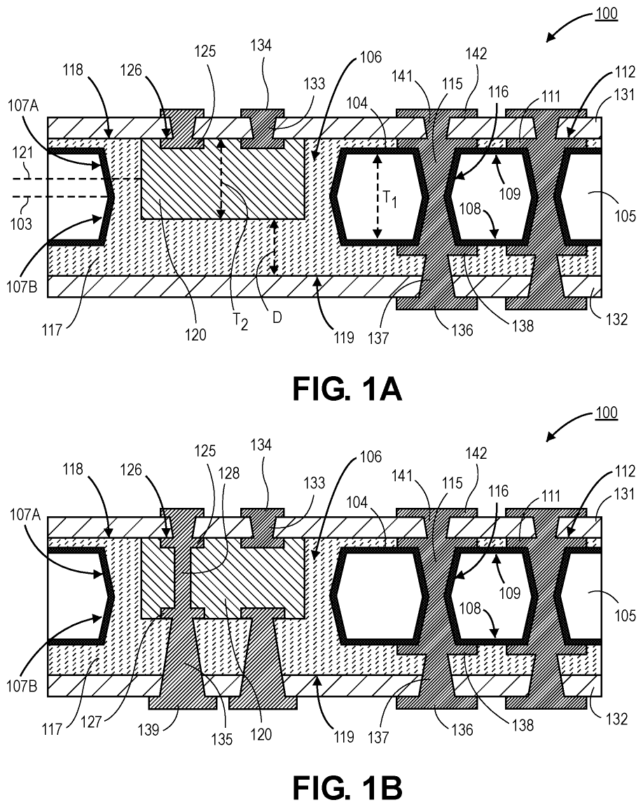

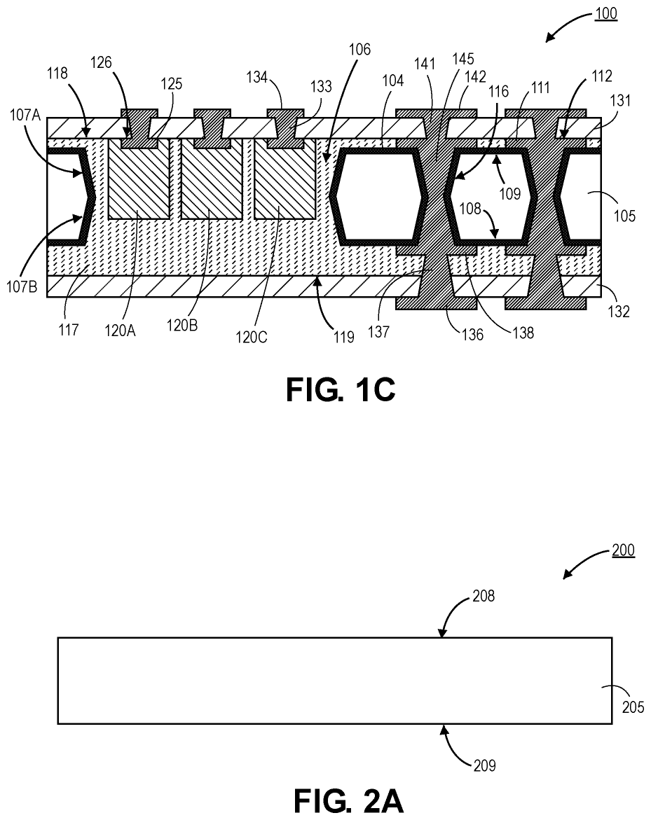

Referring now to FIGS. 1A-1C, a series of cross-sectional illustrations depicting portions of a package substrate 100 with different architectures is shown, in accordance with various embodiments. In FIGS. 1A-1C, the core 105 of the package substrate 100 and first buildup layers 131 and 132 over the core 105 are shown. In an embodiment, the core 105 (which may sometimes be referred to generally as a “substrate”) may be a glass core 105.

In an embodiment, the glass core 105 may be substantially all glass. The glass core 105 may be a solid mass comprising a glass material with an amorphous crystal structure where the solid glass core may also include various structures-such as vias, cavities, channels, or other features—that are filled with one or more other materials (e.g., metals, metal alloys, dielectric materials, etc.). As such, glass core 105 may be distinguished from, for example, the “prepreg” or “FR4” core of a Printed Circuit Board (PCB) substrate which typically comprises glass fibers embedded in a resinous organic material, such as an epoxy.

The glass core 105 may have any suitable dimensions. In a particular embodiment, the glass core 105 may have a thickness that is approximately 50 μm or greater. For example, the thickness of the glass core 105 may be between approximately 50 μm and approximately 1.4 mm. Though, smaller or larger thicknesses may also be used. The glass core 105 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 105 (from an overhead plan view) may be between approximately 10 mm×10 mm and approximately 250 mm×250 mm. In an embodiment, the glass core 105 may have a first side that is perpendicular or orthogonal to a second side. In a more general embodiment, the glass core 105 may comprise a rectangular prism volume with sections (e.g., vias) removed and filled with other materials (e.g., metal, etc.).

The glass core 105 may comprise a single monolithic layer of glass. In other embodiments, the glass core 105 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 105 may each have a thickness less than approximately 50 μm. For example, discrete layers of glass in the glass core 105 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 105 may be any suitable glass formulation that has the necessary mechanical robustness and compatibility with semiconductor packaging manufacturing and assembly processes. For example, the glass core 105 may comprise aluminosilicate glass, borosilicate glass, alumino-borosilicate glass, silica, fused silica, or the like. In some embodiments, the glass core 105 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 105 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 105 may comprise at least 23 percent silicon (by weight) and at least 26 percent oxygen (by weight). In some embodiments, the glass core 105 may further comprise at least 5 percent aluminum (by weight).

In an embodiment, the glass core 105 may be protected by a liner 104 (which may sometimes be referred to as a “buffer”). The liner 104 may be a dielectric material (e.g., an organic dielectric or an inorganic dielectric) that has one or more material properties (e.g., modulus, coefficient of thermal expansion (CTE), etc.) that are between those of the glass core 105 and metallic material (e.g., copper) used to form pads, traces, vias, etc. that would contact the glass core 105 without the presence of the liner 104. The liner 104 allows for more gradual transition in material properties in order to prevent damage to the glass core 105. While liners 104 are shown along the top surface 109, the bottom surface 108, and sidewall surfaces 116 and 107 in embodiments disclosed, some embodiments may omit the liner 104 at one or more locations over the glass core 105.

Referring now to FIG. 1A, a cross-sectional illustration of a portion of a package substrate 100 is shown, in accordance with an embodiment. As shown, the glass core 105 may comprise vias 115 that pass through a thickness of the glass core 105. The vias 115 may have tapered sidewalls 116. For example, double-tapered sidewalls 116 that form an hourglass shaped via 115 is shown in FIG. 1A. Though, a single taper may also be used in some embodiments. The taper of the sidewalls 116 may be indicative of a laser assisted patterning process, as will be described in greater detail herein. In an embodiment, pads 111 and 138 may be provided over and under the vias 115.

In an embodiment, a hole 106 may also be provided through a thickness of the glass core 105. The hole 106 may also have tapered sidewalls 107. For example, a first portion of the sidewall 107A may have a slope in a first direction relative to the top surface 109 of the glass core 105, and a second portion of the sidewall 107B may have a slope in a second (different) direction relative to the top surface 109 of the glass core 105. That is, at least a portion of the sidewall 107 may be non-orthogonal to the top surface 109 of the glass core 105.

In an embodiment, a component 120 may be at least partially located within the hole 106. The component 120 may be similar to any of the components described in greater detail herein. For example, the component 120 may be a MIA in some embodiments. In the illustrated embodiment, a portion of the component 120 may extend above the top surface 109 of the glass core 105. That is, at least a portion of the component 120 may be above (or outside) the hole 106. In an embodiment, the component 120 may comprise one or more pads 125 in order to provide electrical access to the electrical features (e.g., inductors, capacitors, resistors, transistors, etc.) within the component 120. In the illustrated embodiment, the pads 125 are recessed into the component 120 so that the top surface of the component is substantially coplanar with a top surface 126 of the pad 125. Though, in some embodiments, the pads 125 may extend up above a top surface of the component 120.

As used herein, “substantially coplanar” may refer to two surfaces that are within approximately 5 μm of being within the same plane, within 1 μm of being within the same plane, or within 0.5 μm of being within the same plane. “Substantially coplanar” surfaces may refer to surfaces in non-parallel planes that are within 2° of being parallel, within 1° of being parallel, or within 0.5° of being parallel. It is to be appreciated that manufacturing tolerances and manufacturing processes may not be able to provide perfectly flat surfaces, so some amount of surface roughness and/or other non-uniformity may still be considered as satisfying the condition of being “substantially coplanar”.

In an embodiment, a layer 117 may be provided over the top surface 109 and the bottom surface 108 of the glass core 105. The layer 117 may also fill at least a portion of the hole 106. For example, the layer 117 may at least partially embed the component 120. For example, the layer 117 may contact the bottom surface and sidewall surfaces of the component 120. The layer 117 may separate the sidewalls of the component 120 form the sidewalls 107A and/or 107B of the glass core 105 (and the liner 104). The bottom surface of the component 120 may be spaced away from a bottom surface 119 of the layer 117 by a distance D. In some embodiments, a thickness of the layer 117 may be substantially equal to the distance D plus a thickness of the component T₂. In some embodiments, the top surface of the component 120 may not be covered by the layer 117. The layer 117 may also surround the sidewalls of the pads 111 and 138 provided over and under the vias 115. The layer 117 may cover a bottom surface of the pads 138 in some embodiments.

In an embodiment, the layer 117 may be a dielectric material. The dielectric material for the layer 117 may be an organic dielectric material, such as an epoxy or other suitable molding compound. In other embodiments, the dielectric material of the layer 117 may be an inorganic dielectric (e.g., a silicon oxide, a silicon nitride, a carbide, or the like). In some embodiments, the material of the layer 117 is different than a material of the liner 104. In other embodiments, the liner 104 and the layer 117 may be the same material or a similar material. The material of the layer 117 may be tuned for mechanical and/or thermal properties. For example, a CTE of the layer 117 may be closely matched to a CTE of the glass core 105 in order to reduce any CTE mismatch induced stress in the package substrate 100. The layer 117 may also be tuned for higher thermal conductivity in order to enhance heat transfer through a thickness of the glass core 105.

In an embodiment, a top surface 112 of the pads 111, a top surface 118 of the layer 117, and a top surface 126 of the pads 125 may all be substantially coplanar with each other. The coplanar relationship between these surfaces may be the result of a process flow that will be described in greater detail below. Generally, the surface 126 of the pads 125 and the surface 112 of the pads 111 are placed flat against a carrier, and the layer 117 is dispensed over the features of the package substrate 100. As such, the surface 118 of the layer 117 will be supported against the same carrier used to support the pads 125 and 111 in order to provide the described coplanar relationship.

In an embodiment, the core 105 may have a first thickness T₁, and the component 120 may have a second thickness T₂. The first thickness T₁ may be different than the second thickness T₂. That is, the first thickness T₁ may be greater than or less than the second thickness T₂. In other embodiments, the first thickness T₁ may be approximately the same as the second thickness T₂. The difference in thickness and/or the difference in placement between top surfaces of the glass core 105 and the component 120 may result in midlines that are offset from each other. For example, a midline 121 of the component 120 may be offset (in the Z-direction) from a midline 103 of the glass core 105.

In an embodiment, buildup layers 131 and 132 may be provided over the top surface 118 and the bottom surface 119 of the layer 117, respectively. The buildup layers 131 and 132 may be typical organic buildup film or the like. The buildup layers 131 and 132 may be a different material than the layer 117, or one or both of the buildup layers 131 and 132 may be the same material or a similar material as the layer 117. In an embodiment, vias 133 may pass through the buildup layer 131 in order to electrically couple a pad 134 to the pad 125 of the component 120. Vias 141 may pass through the buildup layer 131 in order to electrically couple a pad 142 to the pad 111. In an embodiment, vias 137 may pass through the buildup layer 132 and a portion of the layer 117 in order to electrically couple the pad 136 to pad 138 below the via 115.

Referring now to FIG. 1B, a cross-sectional illustration of a portion of a package substrate 100 is shown, in accordance with an additional embodiment. The package substrate 100 in FIG. 1B may be substantially similar to the package substrate 100 in FIG. 1A, with the exception of the component 120 and interconnects to the component 120. For example, the component 120 may further comprise pads 127 on a bottom surface of the component 120. Providing pads on the bottom surface of the component 120 may allow for backside power delivery or the propagation of power and/or signals through a thickness of the component 120. In some embodiments, the component 120 may also comprise one or more vias 128 through at least a portion of a thickness of the component 120. For example, the vias 128 may sometimes be referred to as being through silicon vias (TSVs) when the component 120 comprises a silicon die, or simply as a through substrate via in other embodiments.

In an embodiment, access to the bottom pads 127 is provided by vias 135 that pass through the buildup layer 132 and a portion of the layer 117. The vias 135 may be formed during the processing used to form the vias 137. Though, different via opening and/or patterning parameters or conditions may be used in order to account for the differences in the depths of the vias 135 compared to the vias 137. The vias 135 may electrically couple the pads 127 to pads 139 provided over the buildup layer 132.

Referring now to FIG. 1C, a cross-sectional illustration of a portion of a package substrate 100 is shown, in accordance with yet another embodiment. In an embodiment, the package substrate 100 in FIG. 1C may be substantially similar to the package substrate 100 in FIG. 1A, with the exception of the number of components 120 that are provided within the hole 106. Instead of a single component 120, a plurality of components 120 may be provided within the hole 106. For example, three components 120A-120C are shown in FIG. 1C. In an embodiment, the plurality of components 120 may all be the same type of component. For example, components 120A-120C may all be MIAs. Other embodiments may comprise a mix of different types of components 120. For example, a first component 120A may be an MIA, a second component 120B may be a DTC, and a third component 120C may be an HBM.

In the embodiments shown in FIGS. 1A-1C, a single hole 106 is shown within the glass core 105. However, it is to be appreciated that a plurality of holes 106 may be provided through the glass core 105. Each of the plurality of holes 106 may comprise one or more components 120. For example, a hole 106 may be located below each of the dies (not shown) provided over the package substrate 100. Though, any arrangement and/or positioning of holes 106 may be used in accordance with embodiments disclosed herein.

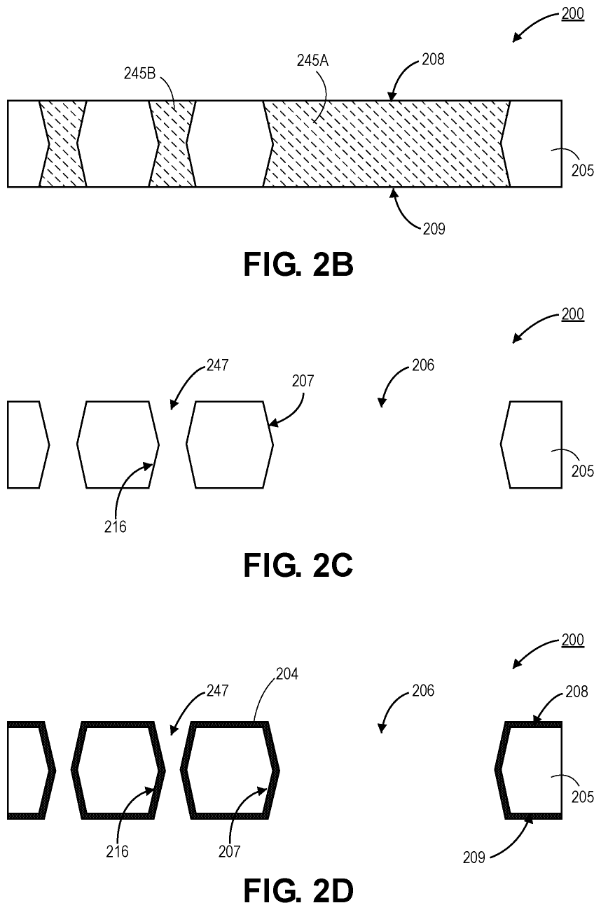

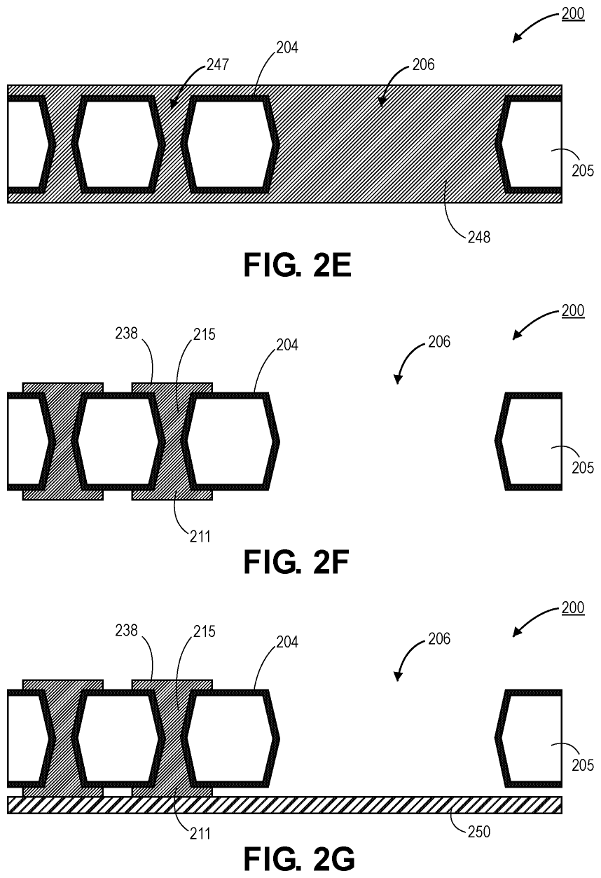

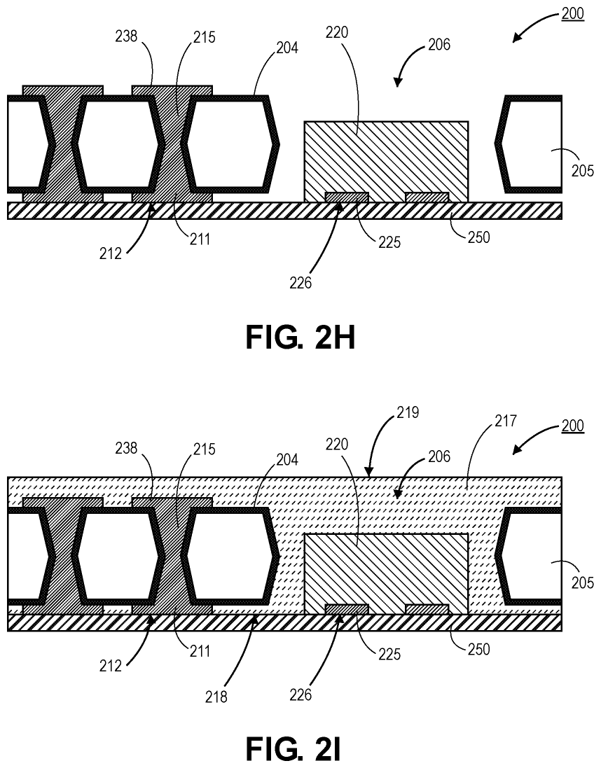

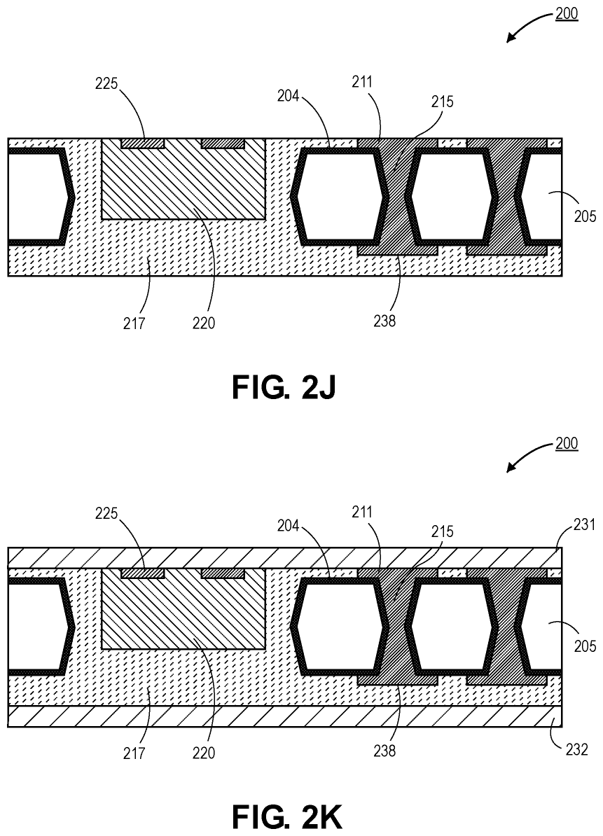

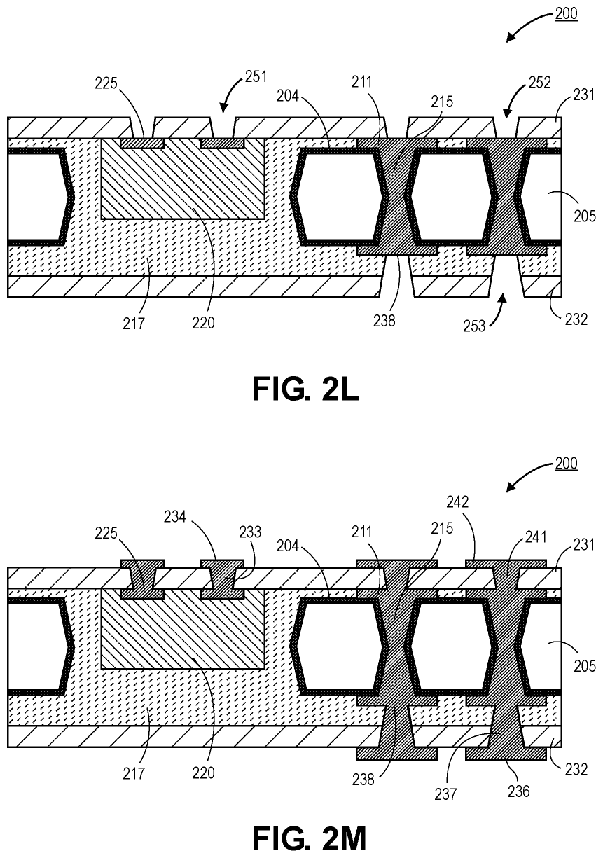

Referring now to FIGS. 2A-2M, a series of cross-sectional illustrations depicting a process for forming a package substrate with a component embedded in a thickness of a glass core is shown, in accordance with an embodiment.

Referring now to FIG. 2A, a cross-sectional illustration of a portion of a package substrate 200 at a stage of manufacture is shown, in accordance with an embodiment. For example, a glass core 205 is shown in FIG. 2A. In an embodiment, the glass core 205 may be similar to any of the glass cores described in greater detail herein. The glass core 205 may comprise a first surface 208 and a second surface 209 opposite from the first surface 208.

Referring now to FIG. 2B, a cross-sectional illustration of the portion of the package substrate 200 after a laser exposure process is shown, in accordance with an embodiment. In an embodiment, the laser exposure process may result in the selective modification of the chemical structure and/or microstructure of the glass core 205 in the exposed regions 245A (where a hole is desired) and the exposed regions 245B (where vias are desired).

Referring now to FIG. 2C, a cross-sectional illustration of the portion of the package substrate 200 after an etching process to form holes through the glass core 205 is shown, in accordance with an embodiment. For example, an etching chemistry (e.g., a wet etching chemistry comprising NaOH or the like) may be applied to the glass core 205 in order to selectively remove the exposed regions 245A and 245B. The removal of the exposed region 245A results in the formation of hole 206, and the removal of the exposed regions 245B results in the formation of via openings 247. As shown, the hole 206 may comprise sloped sidewalls 207 (e.g., double tapered in FIG. 2C) and similarly sloped sidewalls 216 for the via openings 247. The sloped sidewalls 207 and 216 may be characteristic of a laser assisted etching process. Though, it is to be appreciated that embodiments are not limited to such patterning processes in order to form the hole 206 and the via openings 247. Other patterning processes for the glass core 205 may result in different sidewall profiles.

Referring now to FIG. 2D, a cross-sectional illustration of the portion of the package substrate 200 after the liner 204 is applied over the glass core 205 is shown, in accordance with an embodiment. In an embodiment, the liner 204 may be applied with any conformal deposition process. In one embodiment, the liner 204 is applied with a chemical vapor deposition (CVD) process or an atomic layer deposition (ALD) process. The liner 204 may cover the first surface 208, the second surface 209, the sidewall surfaces 207 of the hole 206, and/or the sidewall surfaces 216 of the via openings 247. The liner 204 may be similar to any of the liner materials described herein. For example, the liner 204 may comprise an organic dielectric or an inorganic dielectric.

Referring now to FIG. 2E, a cross-sectional illustration of the portion of the package substrate 200 after a conductive layer 248 is applied over and through the glass core 205 is shown, in accordance with an embodiment. In an embodiment, the conductive layer 248 may be plated with an electrolytic plating process or the like. For example, a seed layer (not shown) may first be formed over the liner 204, and the conductive layer 248 may be plated up from the seed layer. The conductive layer 248 may comprise any suitable electrically conductive material, such as copper or the like. The conductive layer 248 may be provided over the top and bottom surface of the glass core 205 as well as through the via openings 247 and the hole 206.

Referring now to FIG. 2F, a cross-sectional illustration of the portion of the package substrate 200 after the conductive layer 248 is patterned in order to define vias 215 and pads 238 and 211 is shown, in accordance with an embodiment. The conductive layer 248 may be patterned with any suitable lithography and etching process that uses suitable resist layers and/or the like. The patterning process may also comprise removal of the seed layer from portions of the liner 204 between pads 238 or 211, and along the sidewalls of the hole 206. The patterning process may clear the hole 206 to prepare the glass core 205 for subsequent assembly processes.

Referring now to FIG. 2G, a cross-sectional illustration of the portion of the package substrate 200 after the glass core 205 is attached to a carrier 250 is shown, in accordance with an embodiment. In an embodiment, the carrier 250 may comprise a substrate (e.g., a glass substrate, a ceramic substrate, a semiconductor substrate, a metal substrate, or the like). Embodiments may also comprise a carrier 250 that is a tape material. For example, the tape may be stretched across a frame like structure (e.g., a tape frame) in some embodiments. As shown, the portion of the package substrate 200 is placed on the carrier 250 so that the pads 211 are in direct contact with the carrier 250. This may provide a gap between the liner 204 at the bottom of the glass core 205 and the surface of the carrier 250.

Referring now to FIG. 2H, a cross-sectional illustration of the portion of the package substrate 200 after a component 220 is attached to the carrier 250 is shown, in accordance with an embodiment. In an embodiment, the component 220 is set onto the carrier 250 within the hole 206. That is, at least a portion of the component 220 may be within the hole 206. The component 220 may include pads 225 that directly contact the carrier 250. Accordingly, the surface 226 of the pads 225 and the surface 212 of the pads 211 are both supported by the same substantially planar surface of the carrier 250. As such, the surface 226 may be substantially coplanar with the surface 212 in some embodiments. In an embodiment, the component 220 may be placed onto the carrier with any suitable process. For example, a pick-and-place tool may be used, a manual process may be used, or any other process or tool may be used in some embodiments.

Referring now to FIG. 2I, a cross-sectional illustration of the portion of the package substrate 200 after a layer 217 is applied over the glass core 205 is shown, in accordance with an embodiment. In an embodiment, the layer 217 may be a dielectric material, such as an organic dielectric material or an inorganic dielectric material. The layer 217 may be applied with a molding process, a CVD process, or any other suitable deposition process. In an embodiment, the layer 217 fills the gap between the glass core 205 and the carrier 250 and surrounds the pads 211. As such, the surface 218 of the layer 217 may also be substantially coplanar with the surface 226 of pad 225 and the surface 212 of the pad 211. The layer 217 may fill a remaining portion of the hole 206 and cover the top surface of the glass core 205. The layer 217 may also cover the pads 238 on the top end of the vias 215.

Referring now to FIG. 2J, a cross-sectional illustration of the portion of the package substrate 200 after the carrier 250 is removed is shown, in accordance with an embodiment. The core 205 is also flipped over for subsequent processing. In an embodiment, surfaces of the pads 225 and 211 may also be cleaned in some embodiments.

Referring now to FIG. 2K, a cross-sectional illustration of the portion of the package substrate 200 after buildup layers 231 and 232 are applied over the glass core 205 is shown, in accordance with an embodiment. In an embodiment, the buildup layers 231 and 232 may comprise buildup film. The buildup layers 231 and 232 may be applied with a lamination process or the like.

Referring now to FIG. 2L, a cross-sectional illustration of the portion of the package substrate 200 after openings 251, 252, and 253 are formed through the buildup layers 231 and 232 is shown, in accordance with an embodiment. In an embodiment, openings 251, 252, and 253 may be formed with laser ablation processes, lithography and etching processes, or any other suitable patterning process. The openings 251, 252, and 253 may expose pads 225, 211, and 238, respectively. In an embodiment, a seed layer (not shown) may be applied to the buildup layers 231 and 232 for subsequent plating processes.

Referring now to FIG. 2M, a cross-sectional illustration of the portion of the package substrate 200 after vias are formed through the buildup layers 231 and 232 and pads are formed over the buildup layers 231 and 232 is shown, in accordance with an embodiment. The metallic structures of the vias 233, 241, and 237 and the pads 234, 242, and 236 may be formed with a plating process. After the plating, a lithography and etching process may be used to define the pads 234, 242, and 236. The etching process may also remove exposed portions of the seed layer between pads 234, 242, and/or 236.

After the processing in FIG. 2M, the package substrate 200 may continue to be processed by applying more buildup layers and forming electrically conductive structures (e.g., pads, vias, traces, etc.) within the additional buildup layers.

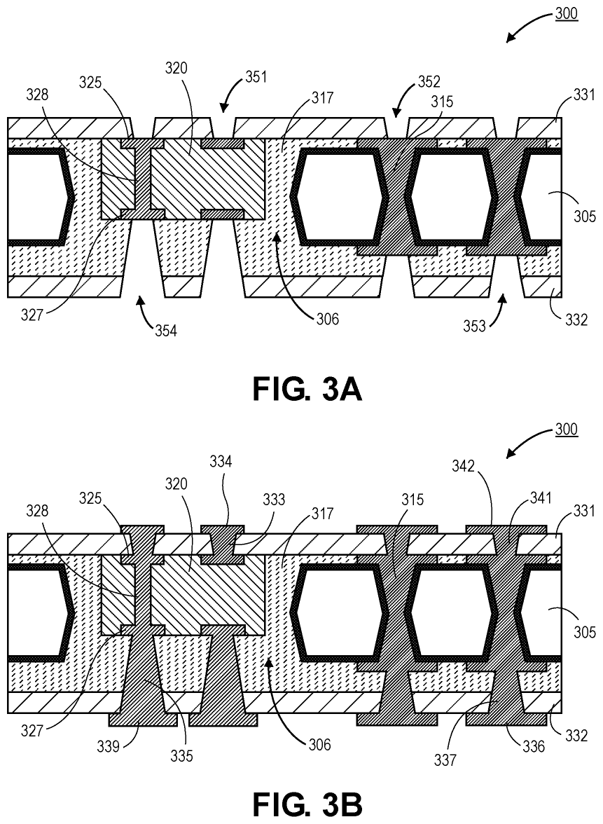

Referring now to FIGS. 3A and 3B, a portion of an alternative process for forming a package substrate 300 is shown, in accordance with an embodiment. The package substrate 300 may be similar to the package substrate 200, with the exception of the component 320. Instead of pads on a single side, pads 325 and 327 (which may be connected by a via 328) are provided on both sides of the component 320. The component 320 may be placed in a hole 306 through the glass core 305 and at least partially embedded by a layer 317 in the hole 306.

In an embodiment, openings 351 are provided through the buildup layer 331 to expose pads 325, and openings 352 are provided through the buildup layer 331 to expose pads of the via 315. On the other side, openings 353 pass through the buildup layer 332 and a portion of the layer 317 to expose the bottom pads of the via 315, and openings 354 pass through the buildup layer 332 and a portion of the layer 317 to expose pads 327 on the bottom of the component 320. All of the openings may be formed with any suitable process, such as laser ablation. Process parameters may be controlled in order to provide the proper depth to the openings in order to expose the respective pad.

Referring now to FIG. 3B, a cross-sectional illustration of the portion of the package substrate 300 after vias are formed through the buildup layers 331 and 332 and pads are formed over the buildup layers 331 and 332 is shown, in accordance with an embodiment. The metallic structures of the vias 333, 335, 341, and 337 and the pads 334, 339, 342, and 336 may be formed with a plating process. After the plating, a lithography and etching process may be used to define the pads 334, 339, 342, and 336. The etching process may also remove any exposed portions of the seed layer between pads 334, 339, 342, and 336.

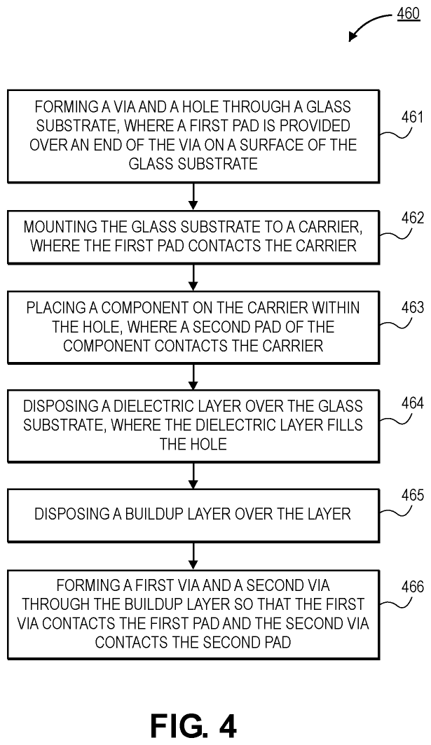

Referring now to FIG. 4, a process flow diagram of a process 460 for forming a package substrate with a component embedded in a hole of a glass core is shown, in accordance with an embodiment. In an embodiment, the process 460 may be similar to and/or include operations similar to any of those described in greater detail herein with respect to FIGS. 2A-2M.

In an embodiment, the process 460 may begin with operation 461, which comprises forming a via and a hole through a glass substrate. In an embodiment, a first pad is provided over an end of the via on a surface of the glass substrate. Though, the first pad may be separated from the surface of the glass substrate by a liner or the like.

In an embodiment, the process 460 may continue with operation 462, which comprises mounting the glass substrate to a carrier. In an embodiment, the first pad contacts the carrier. In an embodiment, the process 460 may continue with operation 463, which comprises placing a component on the carrier within the hole. In an embodiment, a second pad of the component contacts the carrier. As such a surface of the first pad and a surface of the second pad are substantially coplanar with each other.

In an embodiment, the process 460 may continue with operation 464, which comprises disposing a dielectric layer over the glass substrate. In an embodiment, the dielectric layer fills the hole. The dielectric layer may also embed the component. In an embodiment, a surface of the dielectric layer is also substantially coplanar with the surface of the first pad and the surface of the second pad.

In an embodiment, the process 460 may continue with operation 465, which comprises disposing a buildup layer over the layer. The buildup layer may be applied after the carrier is removed and the surfaces of the first pad and the second pad are exposed. The buildup layer may be applied with a lamination process or the like.

In an embodiment, the process 460 may continue with operation 466, which comprises forming a first via and a second via through the buildup layer so that the first via contacts the first pad and the second via contacts the second pad. Additional buildup layers with pads, traces, vias, etc. may then be added in order to form a complete package substrate with the glass substrate functioning as a glass core.

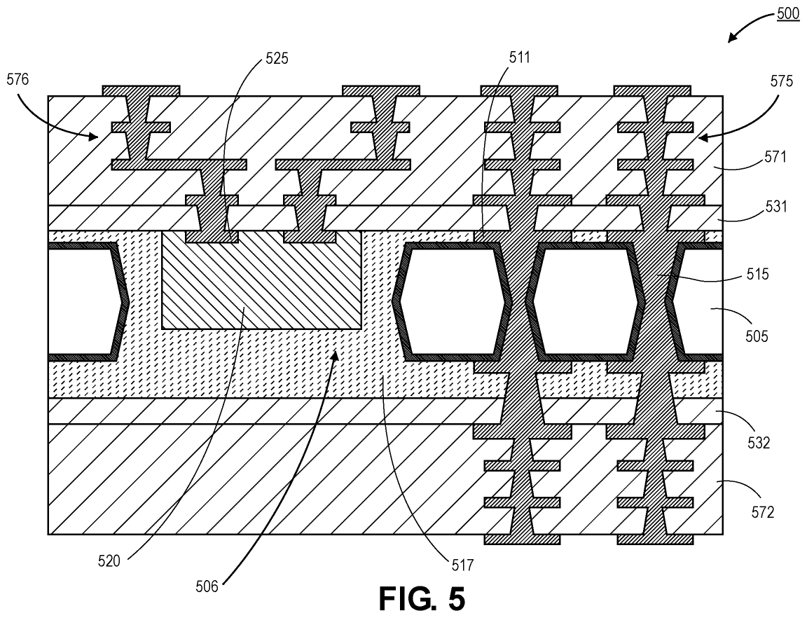

Referring now to FIG. 5, a cross-sectional illustration of a package substrate 500 is shown, in accordance with an embodiment. In an embodiment, the package substrate 500 may comprise a glass core 505. Vias 515 may pass through a thickness of the glass core 505. In an embodiment, a hole 506 is adjacent to the vias 515, and a component 520 is set at least partially into the hole. In an embodiment, the component 520 may be similar to any of the components described in greater detail herein. In an embodiment, a layer 517 embeds the component 520 and fills a remaining portion of the hole 506. The layer 517 may also be provided over and/or under the glass core 505. The component 520 may have pads 525 that have surfaces that are substantially coplanar with surfaces of pads 511 over the vias 515 and with a surface of the layer 517.

In an embodiment, first buildup layers 531 and 532 may be provided over the layer 517. Additional buildup layers 571 and 572 may be provided. Electrical routing 575 (e.g., pads, vias, traces, etc.) may electrically couple the vias 515 to a top surface of the package substrate 500, and electrical routing 576 may electrically couple the component 520 to the top surface of the package substrate 500. The package substrate 500 may include features similar to those included in any of the package substrates described in greater detail herein.

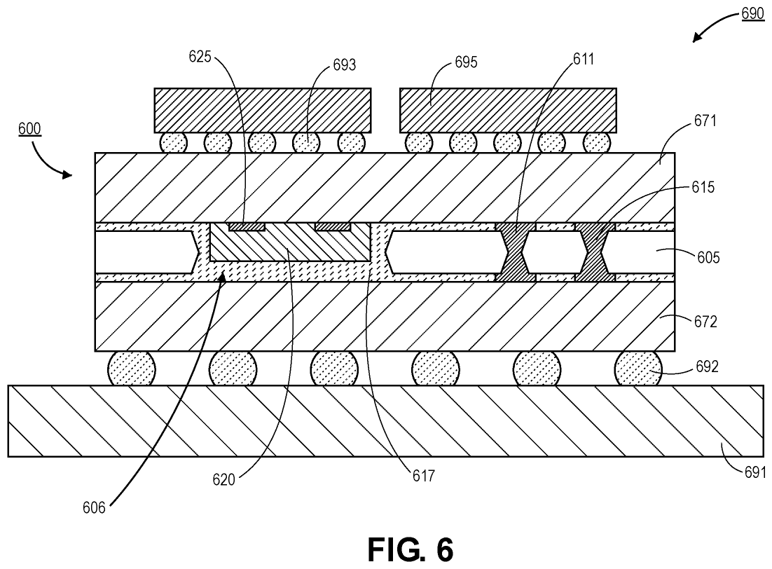

Referring now to FIG. 6, a cross-sectional illustration of an electronic system 690 is shown, in accordance with an embodiment. The electronic system 690 may comprise a board 691, such as a printed circuit board (PCB), a motherboard, or the like. The board 691 may be coupled to a package substrate 600 through second level interconnects (SLIs) 692. The SLIs 692 may comprise solder joints, pins, sockets, or the like.

In an embodiment the package substrate 600 may be similar to any of the package substrates described in greater detail herein. For example, the package substrate 600 may comprise a glass core 605 with buildup layers 671 and 672 over and under the glass core 605. In an embodiment, vias 615 may be provided through a thickness of the glass core 605. A hole 606 for accommodating a component 620 may also be provided through the thickness of the glass core 605. A dielectric layer 617 may embed the component 620 and be provided over and under the glass core 605. In an embodiment, pads 625 of the component, pads 611 of the vias 615, and a top surface of the layer 617 may be substantially coplanar with each other. The component 620 may be similar to any of the components described in greater detail herein. For example, the component 620 may comprise an MIA.

In an embodiment, one or more dies 695 may be electrically coupled to the package substrate 600 through first level interconnects (FLIs) 693. The FLIs 693 may comprise solder bumps, copper bumps, hybrid bonding interfaces, and/or the like. In an embodiment, the dies 695 may be any type of die, such as a central processing unit (CPU), a graphics processing unit (GPU), an XPU, a communications die, a memory die, or the like.

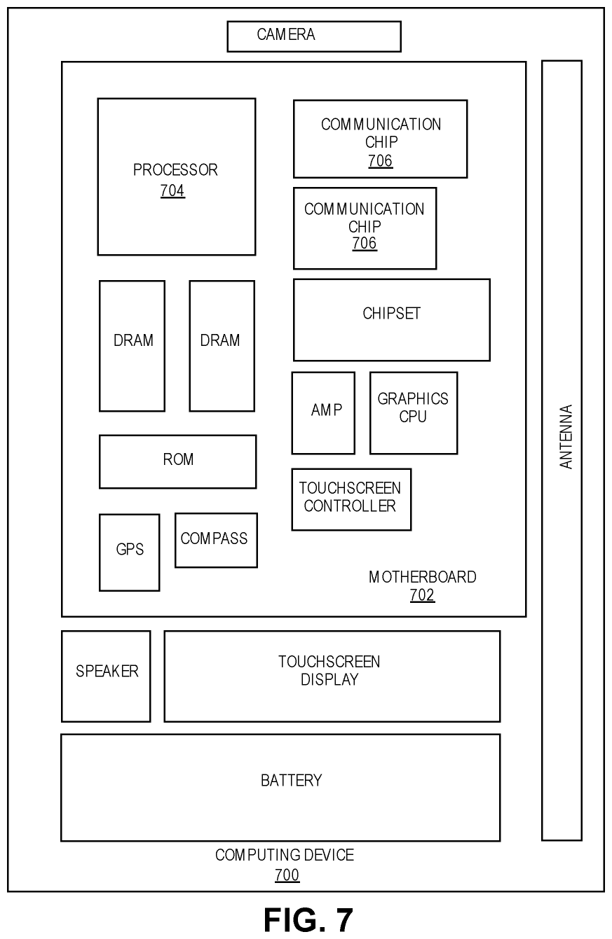

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic package that comprises a package substrate with a glass core with an embedded component, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic package that comprises a package substrate with a glass core with an embedded component, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus comprising: a substrate, wherein the substrate comprises a glass layer; a hole through a thickness of the substrate; a component in the hole, wherein the component comprises a first pad; a via through a thickness of the substrate, wherein a second pad is over an end of the via, and wherein a first surface of the first pad is substantially coplanar with a second surface of the second pad; and a layer over the substrate, wherein the layer fills at least a portion of the hole.

Example 2: the apparatus of Example 1, wherein the component comprises one or more of an inductor, a resistor, or a capacitor.

Example 3: the apparatus of Example 1 or Example 2, wherein the component comprises a processor and/or a memory.

Example 4: the apparatus of Examples 1-3, wherein the component has a first thickness and the substrate has a second thickness that is greater than the first thickness.

Example 5: the apparatus of Example 4, wherein the component has a first midline and the substrate has a second midline, and wherein the first midline is offset from the second midline.

Example 6: the apparatus of Examples 1-5, wherein the component further comprises a third pad on a third surface of the component opposite from the first pad, and wherein a second via through the layer contacts the third pad.

Example 7: the apparatus of Example 6, further comprising a third via through the component, wherein the third via electrically couples the first pad to the third pad.

Example 8: the apparatus of Examples 1-7, wherein sidewalls of the hole are tapered.

Example 9: the apparatus of Examples 1-8, wherein the layer comprises an organic dielectric material or an inorganic dielectric material.

Example 10: the apparatus of Examples 1-9, further comprising: a plurality of components in the hole.

Example 11: an apparatus, comprising: a substrate with a hole through a thickness of the substrate, wherein the substrate comprises a glass material; a layer over a first surface and a second surface of the substrate, wherein the layer fills at least a portion of the hole, and wherein the layer is a dielectric material; and a component with a third surface and a fourth surface, wherein the layer covers the third surface or the fourth surface, and wherein the component is at least partially within the hole.

Example 12: the apparatus of Example 11, wherein the third surface and the fourth surface of the component are both offset from the first surface and the second surface of the substrate.

Example 13: the apparatus of Example 11 or Example 12, wherein the hole has a sidewall that is non-orthogonal to the first surface and the second surface of the substrate.

Example 14: the apparatus of Example 13, wherein the sidewall has a first slope and a second slope.

Example 15: the apparatus of Examples 11-14, wherein the layer comprises an organic dielectric material.

Example 16: the apparatus of Examples 11-15, wherein the layer comprises an inorganic dielectric material.

Example 17: the apparatus of Examples 11-16, wherein the substrate is a core of a package substrate, and wherein the apparatus further comprises: a board coupled to a fifth surface of the package substrate; and a die coupled to a sixth surface of the package substrate opposite from the fifth surface of the package substrate.

Example 18: an apparatus, comprising: a core, wherein the core comprises a glass layer; buildup layers over and under the core; a component at least partially embedded within the core, wherein sidewalls of the component are separated from the core by a layer; and a pad on the component, wherein a first surface of the pad facing a nearest buildup layer is substantially coplanar with a second surface of the layer.

Example 19: the apparatus of Example 18, wherein the component comprises one or more of an inductor, a capacitor, a resistor, a processor, or a memory.

Example 20: the apparatus of Example 18 or Example 19, wherein the component has a first thickness and the core has a second thickness that is different than the first thickness.

What is claimed is:

1. An apparatus comprising:
a substrate, wherein the substrate comprises a glass layer;
a hole through a thickness of the substrate;
a component in the hole, wherein the component comprises a first pad;
a via through a thickness of the substrate, wherein a second pad is over an end of the via, and wherein a first surface of the first pad is substantially coplanar with a second surface of the second pad; and
a layer over the substrate, wherein the layer fills at least a portion of the hole.

2. The apparatus of claim 1, wherein the component comprises one or more of an inductor, a resistor, or a capacitor.

3. The apparatus of claim 1, wherein the component comprises a processor and/or a memory.

4. The apparatus of claim 1, wherein the component has a first thickness and the substrate has a second thickness that is greater than the first thickness.

5. The apparatus of claim 4, wherein the component has a first midline and the substrate has a second midline, and wherein the first midline is offset from the second midline.

6. The apparatus of claim 1, wherein the component further comprises a third pad on a third surface of the component opposite from the first pad, and wherein a second via through the layer contacts the third pad.

7. The apparatus of claim 6, further comprising a third via through the component, wherein the third via electrically couples the first pad to the third pad.

8. The apparatus of claim 1, wherein sidewalls of the hole are tapered.

9. The apparatus of claim 1, wherein the layer comprises an organic dielectric material or an inorganic dielectric material.

10. The apparatus of claim 1, further comprising:
a plurality of components in the hole.

11. An apparatus, comprising:
a substrate with a hole through a thickness of the substrate, wherein the substrate comprises a glass material;
a layer over a first surface and a second surface of the substrate, wherein the layer fills at least a portion of the hole, and wherein the layer is a dielectric material; and
a component with a third surface and a fourth surface, wherein the layer covers the third surface or the fourth surface, and wherein the component is at least partially within the hole.

12. The apparatus of claim 11, wherein the third surface and the fourth surface of the component are both offset from the first surface and the second surface of the substrate.

13. The apparatus of claim 11, wherein the hole has a sidewall that is non-orthogonal to the first surface and the second surface of the substrate.

14. The apparatus of claim 13, wherein the sidewall has a first slope and a second slope.

15. The apparatus of claim 11, wherein the layer comprises an organic dielectric material.

16. The apparatus of claim 11, wherein the layer comprises an inorganic dielectric material.

17. The apparatus of claim 11, wherein the substrate is a core of a package substrate, and wherein the apparatus further comprises:
a board coupled to a fifth surface of the package substrate; and
a die coupled to a sixth surface of the package substrate opposite from the fifth surface of the package substrate.

18. An apparatus, comprising:
a core, wherein the core comprises a glass layer;
buildup layers over and under the core;
a component at least partially embedded within the core, wherein sidewalls of the component are separated from the core by a layer; and
a pad on the component, wherein a first surface of the pad facing a nearest buildup layer is substantially coplanar with a second surface of the layer.

19. The apparatus of claim 18, wherein the component comprises one or more of an inductor, a capacitor, a resistor, a processor, or a memory.

20. The apparatus of claim 18, wherein the component has a first thickness and the core has a second thickness that is different than the first thickness.
